(19) United States
(12) Patent Application Publication
(10) Pub. No.: US 2009/0134495 A1
(43) Pub. Date: May 28, 2009

(54) Method of designing semiconductor device

(75) Inventor: Keiichirou Kondou, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/292,202

(22) Filed: Nov. 13, 2008

(30) Foreign Application Priority Data
Nov. 22, 2007 (JP) 2007-303374

(51) Int. Cl. H01L 23/02; H01L 21/50

(52) U.S. Cl. 257/620; 438/652; 257/E23.18; 257/E21.499

(57) ABSTRACT

A design method of a semiconductor device comprising forming a base wafer by using a plurality of semiconductor chips including a plurality of functional macros, generating macro test information by testing the plurality of function macros of the plurality of semiconductor devices; and picking a macro that is prohibited from being used out of the plurality of function macros based on the macro test information and a net list of user circuit. Since tests are carried out at the phase of a base wafer, it is possible to improve yield rates in the manufacture of semiconductor integrated circuits.

### BACKGROUND

1. Field of the Invention

The present invention relates to a method of designing a semiconductor device. In particular, the present invention relates to a method of designing a structured ASIC (Application Specific Integrated Circuit) in which a desired semiconductor device having various functions is designed by designing a wiring layer for the semiconductor device on which a plurality of function macros and function cells are previously embedded.

2. Description of Related Art

FPGAs (Field Programmable Gate Arrays) have been well known as devises that are developed in a short period and can be re-programmed in the field of semiconductor devices. Furthermore, ASICs have been also well known as ICs that are used for specific applications and must be produced in large volume even though they are large-scale circuits and designing them is quite difficult. In recent years, semiconductor devices called “structured ASICs” have become widespread as intermediate semiconductor devices between the FPGAs and ASICs.

The structured ASIC is a kind of technique in which a plurality of function macros such as SRAMs (Static Random Access Memories) and PLLs (Phase Locked Loops), and a plurality of function cells such as invertors and flip-flops are built into a wafer in advance by using several wiring layers, and then the wafer is customized by using a relatively small number of upper wiring layers in order to design desired circuits.

By preparing a wafer in which function macros and function cells are formed in advance, a desired semiconductor device can be manufactured just by forming a few upper wiring layers. Therefore, the use of such a structured ASIC allows a shorter development period than that of a conventional ASIC and the design of a more complex circuit than that of a FPGA.

Meanwhile, it is impossible to completely eliminate accuracy variation between manufacturing devices, the mixing of foreign substances, and the like in a manufacturing process of semiconductor devices. Such variation between manufacturing devices and a mixing of foreign substances may result in semiconductor chips having a defective portion therein scattered over the wafer. Accordingly, as one of well-known technique, Japanese Examined Patent Publication No. 6-101511 (Okamoto) discloses a method of managing data about defective products. In the technique described in Okamura, test results are summarized for each test step, and then summarized for all test steps.

Furthermore, a technique using redundant cells for memory cells or the like is also known as one of techniques to improve a yield rate in such a case where semiconductor devices are found to have defective cells. In memory devices or the likes, redundant cells are prepared in advance. Then, when an original cell is found to be defective, that original cell is replaced with one of the redundant cells, so that the yield rate is improved.

### SUMMARY

However, Okamoto discloses merely a technique to summarize test results, and does not give any thought to improvements in a yield rate of structured ASICs like the ones described above. Furthermore, in a method using redundant cells to improve a yield rate, extra redundant cells need to be formed in a semiconductor device in advance, and thereby increasing the circuit area. In a structured ASIC like the one described above, since circuits corresponding to various function macros are built into the chip in advance, the preventive provision of the circuits that are used to substitute for a circuit when the circuit is found to be defective in a similar manner to the redundant cells may wastefully increase the circuit area. Accordingly, it has been desired to develop a design technique capable of improving a yield rate of semiconductor devices even in the case of structured AISCs.

A first exemplary aspect of an embodiment of the present invention is a design method of a semiconductor device comprising forming a base wafer by using a plurality of semiconductor chips including a plurality of functional macros, generating macro test information by testing the plurality of function macros of the plurality of semiconductor devices, and picking a macro that is prohibited from being used out of the plurality of function macros based on the macro test information and a net list of user circuit.

Since macro test information is created by carrying out tests in the phase of a base wafer in such a manner, a yield rate in the manufacture of semiconductor integrated circuits, especially structured ASICs can be improved.

A yield rate in the manufacture of semiconductor integrated circuits can be improved.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1A shows a base wafer and FIG. 1B shows one of the chips formed on the base wafer;

FIG. 2 shows tests carried out for a base wafer and macro test information created by the tests;

FIG. 3 shows a map created by tests;

FIG. 4 shows a screening result indicating passes/fails created by tests;

FIG. 5 shows a non-defective rate map created by tests;

FIG. 6 shows a characteristic map created by tests;

FIG. 7 shows a flow to determine macros that are prohibited from being placed;

FIG. 8 shows a non-defective rate map with the non-defective rate of 100%;

FIG. 9 shows a non-defective rate map with the non-defective rate of 90%;

FIG. 10 shows a flow to design a user circuit; and

FIG. 11 shows a flow to determine macros that are prohibited from being placed when their characteristics are also taken into consideration.

### DETAILED DESCRIPTION OF THE EXEMPLARY EMBODIMENTS

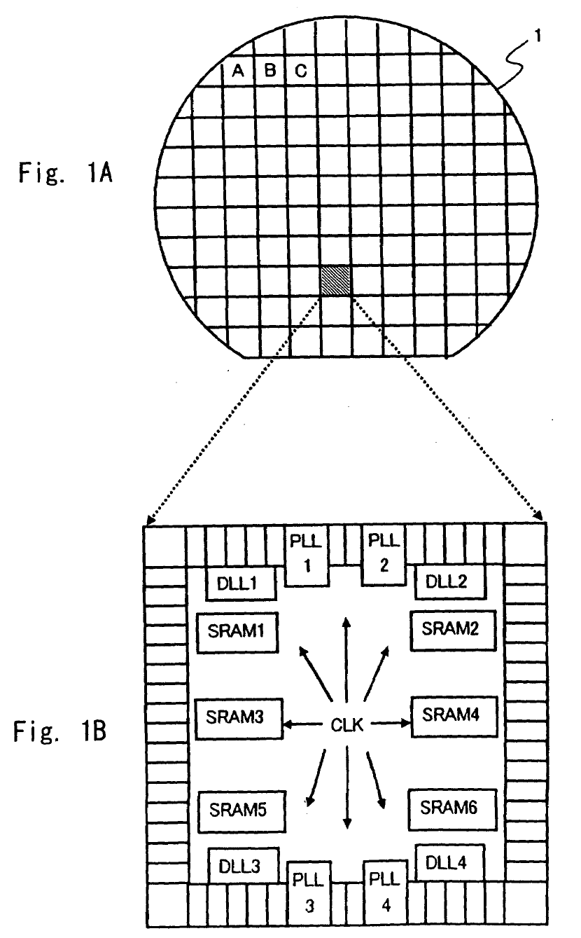

Exemplary embodiments in accordance with the present invention are explained hereinafter with reference to the drawings. FIGS. 1, 2, 3, and 4 show schematic diagrams, flowcharts, and the likes for illustrating an exemplary embodiment in accordance with the present invention. In the following explanations, exemplary embodiments in accordance with the present invention are explained by using FIGS. 1-4 as appropriate.

In an exemplary embodiment in accordance with the present invention, a plurality of wafers (which are called “base wafers” hereinafter) 1 are first prepared in a state before the manufacture of semiconductor devices using a structured ASIC technique is completed. This base wafer 1 is a kind of wafer in which various elements, logic gates, and the likes formed on the semiconductor substrate are connected by several wiring layers formed on the semiconductor substrate in order to form a plurality of function macros (which is also called “macros” hereinafter) and function cells. The term “function macro” means, for example, a PLL, a DLL (Delay Locked Loop), a SRAM, and the like. That is, the base wafer 1 is a wafer in a state where these function macros, as well as clock tree lines, power supply lines, and the likes are formed thereon. FIG. 1A shows a base wafer 1, and FIG. 1B is a schematic diagram showing a chip 2 in a state when the base wafer 1 is formed.

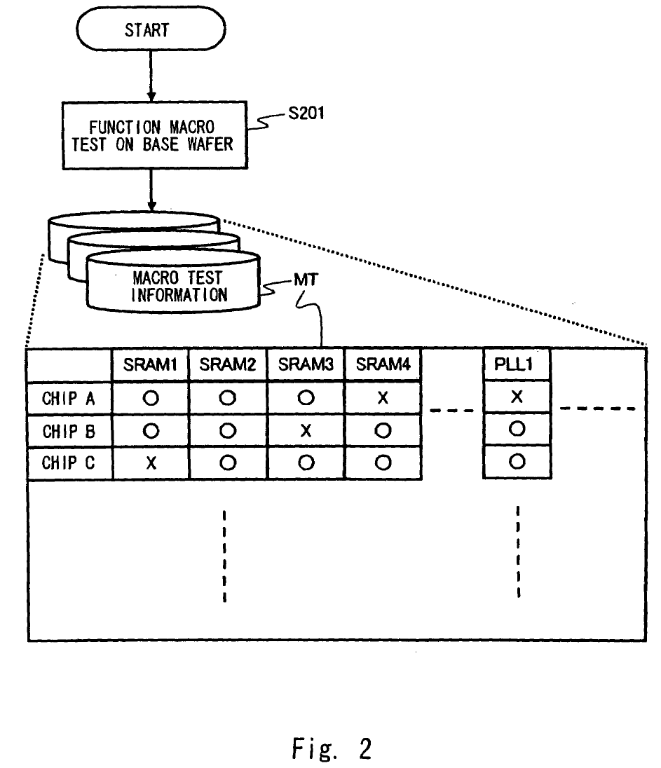

FIG. 2 is a flowchart showing tests carried out for a base wafer. As shown in FIG. 2, various tests are carried out for the base wafer 1 at the time when the base wafer 1 shown in FIG. 1A is formed in an exemplary embodiment in accordance with the present invention (see the step S201 in FIG. 2). The tests carried out at this point include function tests to determine whether each of function macros (e.g., a PLL and a SRAM) formed on the base wafer can perform its function properly or not, and characteristic tests to evaluate the circuit characteristics of each function macro such as a voltage margin and an operating frequency margin. These test results are associated with identification information for each chip as measurement results indicating passes/fails of the function macros and measurement results of characteristics, so that macro test information MT is produced.

This macro test information is explained hereinafter with the base wafer 1 and the chip 2 shown in FIGS. 1A and 1B. The macro test information MT contains and associates chip information in the base wafer 1 and the macro test results. For example, it contains such information that PLL 1 and SRAM 4 shown in FIG. 1B cause malfunction in a chip located in a position indicated by the letter A in FIG. 1A, and DLL 1 and SRAM 3 shown in FIG. 1B cause malfunction in a chip located in a position indicated by the letter B in FIG. 1A.

The macro test information MT can be produced, for example, as data in a table shown in FIG. 2. FIG. 2 shows a single table indicating functional pass/fail of each macro. However, this table is not necessarily composed of a single table, and can be composed of plural tables each of which is created for corresponding one of various tests such as a voltage margin test and an operating frequency margin test that are carried out in the phase of the base wafers 1.

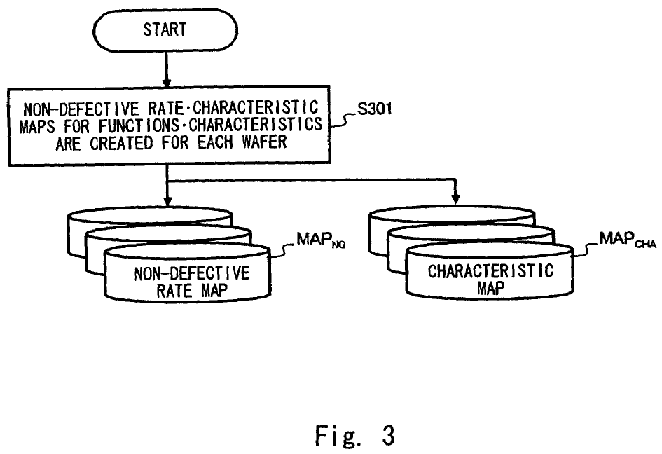

After that, data contained in the macro test information MT obtained by the tests on the base wafers 1 is associated with identification information for each of the base wafers 1. Then, using the macro test information MT, a non-defective rate map MAP_{NG} and a characteristic map MAP_{CHA} are created for each of the base wafers in accordance with the flow shown in FIG. 3. A non-defective rate map MAP_{NG} and a characteristic map MAP_{CHA} in accordance with an exemplary embodiment of the present invention are explained hereinafter using an example in which several base wafers 1 shown in FIG. 1, e.g., a wafer 1a, a wafer 1b, and a wafer 1c are prepared. Note that the following explanation is made with an assumption that each base wafer 1 has 10 chips formed thereon for the simplification of the explanation.

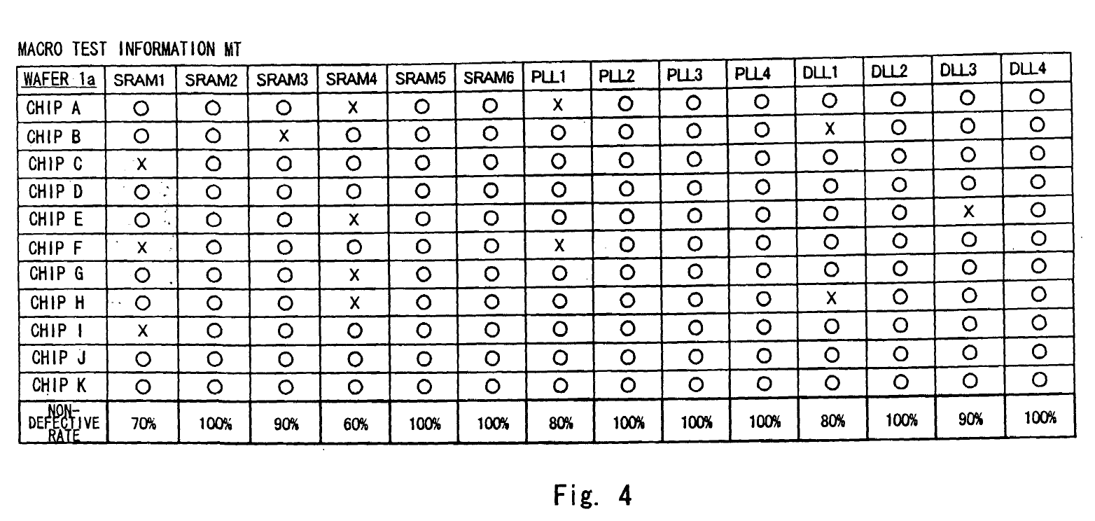

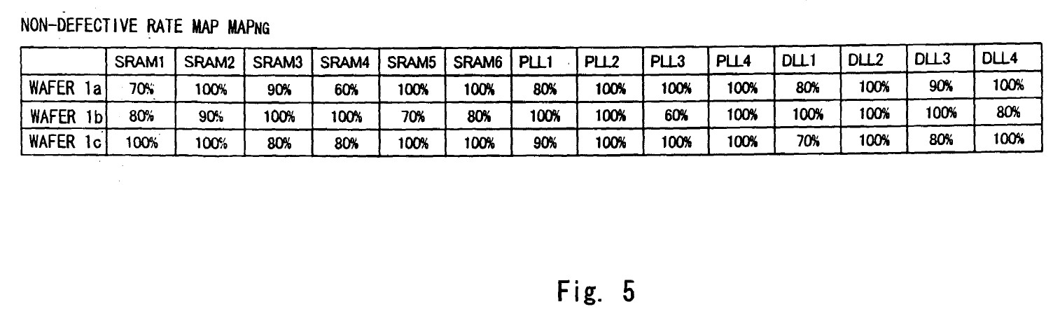

Assume that the result relating to the function tests that are carried out on the first base wafer 1a to obtain the macro test information MT becomes the one shown in FIG. 4. From such a result shown in FIG. 4, the non-defective rate for each function macro in the wafer 1a can be obtained as shown in the last row in FIG. 4. By summarizing these non-defective rates on a wafer-by-wafer basis, a non-defective rate map MAP_{NG} expressed on a wafer-by-wafer basis can be obtained as shown in FIG. 5.

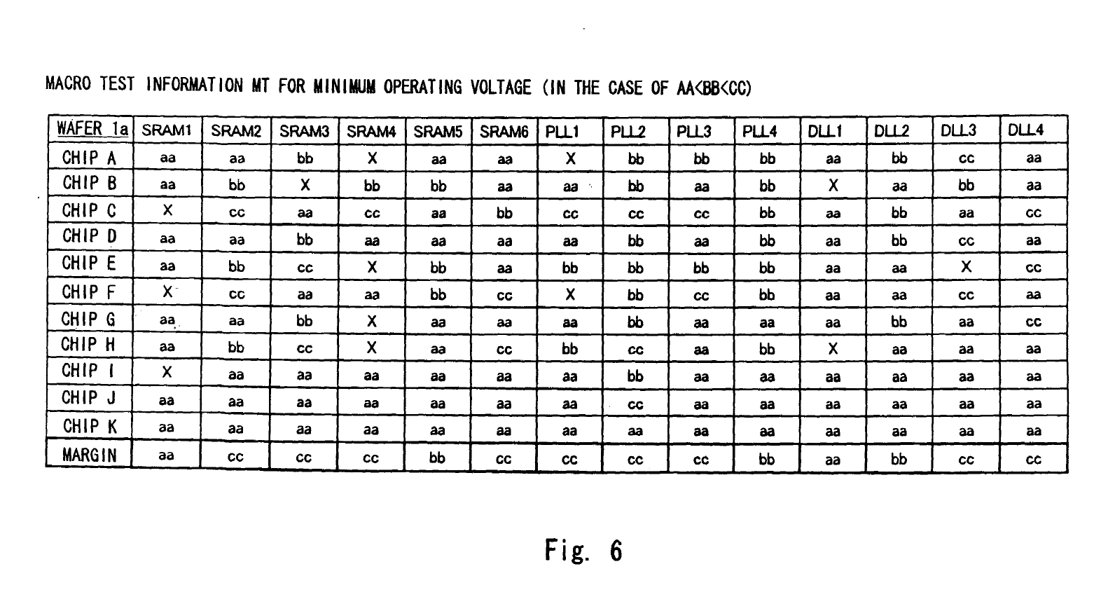

A characteristic map MAP_{CHA} can be, for example, formed in the following manner. Tables such as a minimum operating voltage table for each chip and a minimum operating frequency table for each chip are created in accordance with test items carried out in the phase of the base wafer 1 in a similar format to that of the macro test information MT shown in FIG. 4. The macro test information MT obtained in this manner is schematically shown in FIG. 6. Then, taking the minimum operating voltage of SRAM 1 as an example, the highest minimum operating voltage among the minimum operating voltages of SRAMs 1 of a plurality of chips formed in the base wafer la is used as the value for the lower voltage margin. Assuming a case where the minimum operating voltages are compared among three chips, and the minimum operating voltage of the SRAM 1 of a chip A is aa (V), the minimum operating voltage of a chip B is bb (V), and the minimum operating voltage of a chip C is cc (V), and their relation is expressed as a formula aa<bb<cc, the worst minimum operating voltage among the three minimum operating voltage, i.e., the voltage cc (V) is defined as the lowvoltage operating margin. If the same base wafer 1a as the base wafer shown in FIG. 4 is used, the minimum operating voltage for each function macro in the wafer 1a is expressed as shown in the last row in FIG. 6.

Although FIG. 6 shows the minimum operating voltage as an example of the lower voltage margin, similar tables can be also created for other various characteristics. Then, a characteristic map MAP_{CHA} can be created by listing those characteristics on a wafer-by-wafer basis in a similar manner to the table shown in FIG. 5.

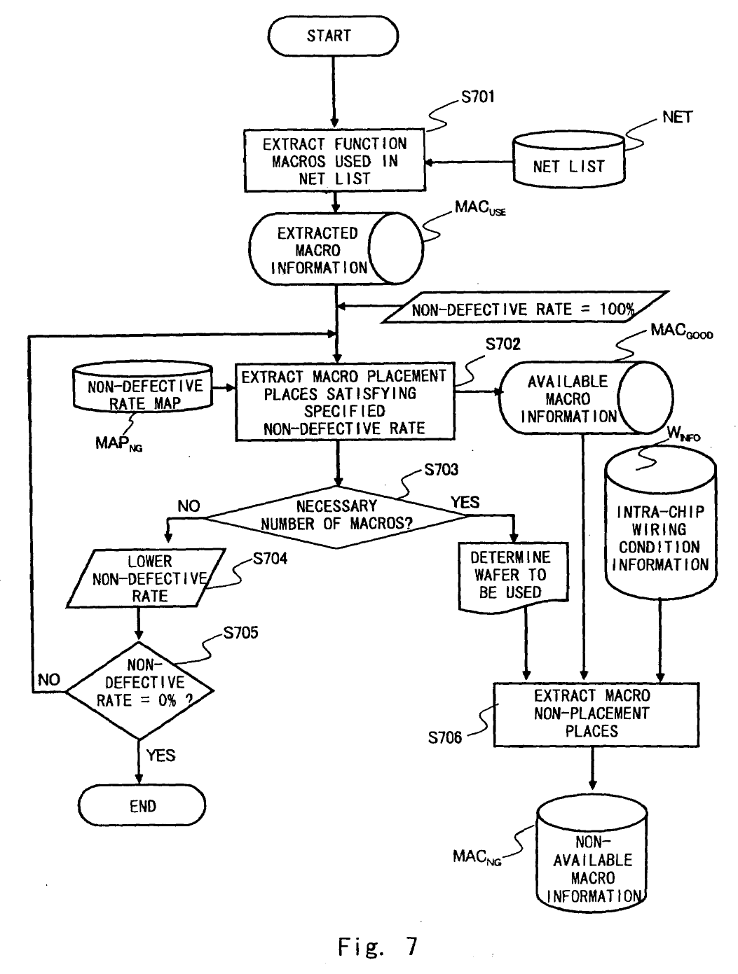

In an exemplary embodiment in accordance with the present invention, after the base wafer 1 is prepared, the base wafer 1 is kept intact with the created macro test information MT, the non-defective MAP_{NG}, and the characteristic MAP_{CHA}. Then, the process proceeds to the phase of the next flow shown in FIG. 7.

A net list NET for the circuit connection information of a user circuit (circuit to be completed as a transferred ASIC) is taken in at a step S701 in FIG. 7. Then, macros that are used in the user circuit are extracted from the net list information of the user circuit at the step S701. The macros extracted at this point are output as extracted macro information MAC_{USE}. In this example, the extracted macro information MAC_{USE} is information expressed as “number of macros used in user circuit: PLL=2, SRAM=4”. The extracted macro information MAC_{USE} is stored, for example, in a temporally storage device in the designing apparatus.

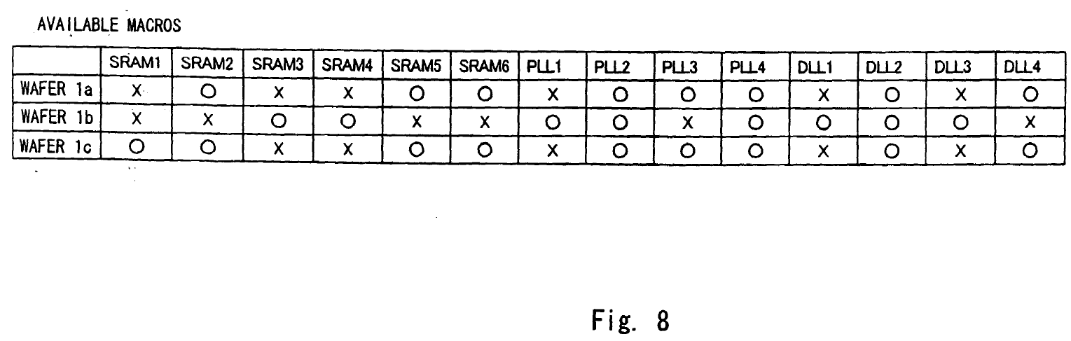

After that, it is determined which macros in which places are available on the chip using the non-defective rate map MAP_{NG} shown in FIG. 5 at a step S702. At this point, when the step S702 is performed for the first time, the initial value to specify the place of an available macro is defined as the places of macros where the non-defective rates are 100%. For example, assume that the user circuit uses a PLL. In the non-defective rate map shown in FIG. 5, PLL 2, PLL 3, and PLL 4 in the wafers 1a and 1c, and PLL 1, PLL 2, and PLL 4 in the wafer 1b have the 100% non-defective rates. Therefore, it is established so that these PLLs having 100% non-defective rates are used, and this information is stored in a temporally storage device or the like. Similarly, it is also established for other function macros such that macros having 100% non-defective rates are defined to be available macros, and this information is stored in the temporally storage device or the like as available macro information MAC_{GOOD}. When the information shown in FIG. 5 is used, the available macros are represented as shown in FIG. 8.

At a step S703, it is determined whether or not the number of macros that are defined to be available at the step S702 satisfies the requirement for the number of macros necessary for the user circuit. Assume that the user circuit needs two PLLs and four SRAMs as with the example described above. There are three or four SRAMs, which can use, in each of the wafers 1a and 1b in the non-defective rate map shown in FIG. 5. Therefore, the wafer 1c, which has necessary number of available macros for the user circuit, is designated as the base wafer used to produce the user circuit at the step S703, and the process proceeds to a step S706.

At this point, a case in which the wafer 1c shown in FIG. 5 does not exist, i.e., only base wafers 1a and 1b exist is explained hereinafter. When only base wafers 1a and 1b exist, there is no wafer that has sufficient number of available macros for the user circuit. Therefore, the process proceeds to a step S704.

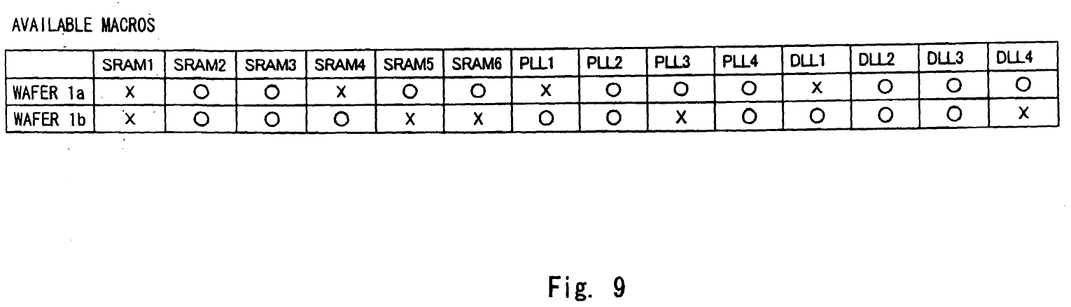

At the step S704, the initial value, which is defined as non-defective rate=100%, is decreased. The decrease of the non-defective rate should be preferably as small as possible (e.g., 1%). However, the non-defective rate is decreased by 10%, i.e., is defined as non-defective rate=90% in this example for the simplification of the explanation. After the non-defective rate is decreased at the step S704, the decision represented as a step S705 is made. Then, the process returns to the step S702, and macros having 90% non-defective rates or higher are defined to be available macros in the next routine. When the non-defective rate is lowered to 90%, the map of available macros for the wafers 1a and 1b is changed to the map shown in FIG. 9. After that, the process proceeds to the step S703 again, and the comparisons with the numbers of the necessary macros are carried out. In the case of the table shown in FIG. 9, the wafer 1a is selected as an available base wafer.

After that, the decrease of the non-defective rate and the establishment of available macros are repeated. Then, if the non-defective rate is decreased to 0% at the step S704, it means that the chips in the currently-prepared base wafers 1 cannot cover all the macro functions necessary for the user circuit, so that the designing process are terminated. This decision is made at the step S705 in FIG. 7. When there is not any available base wafer even with 0% non-defective rate, the user circuit needs to be changed, or the base wafer itself must be changed.

At the step S703, if the base wafer satisfies the necessary number of the function macros used in the user circuit, the wafer that is actually used for the user circuit is determined. At the step S706, the macros that are prohibited from being used are determined based on the available macro information MAC_{GOOD} created at the step S702 and pre-established intra-chip wiring-placement condition information W_{INFO}. At this point, the information about the macros that are prohibited from being used is output as non-available macro information MAC_{NG}.

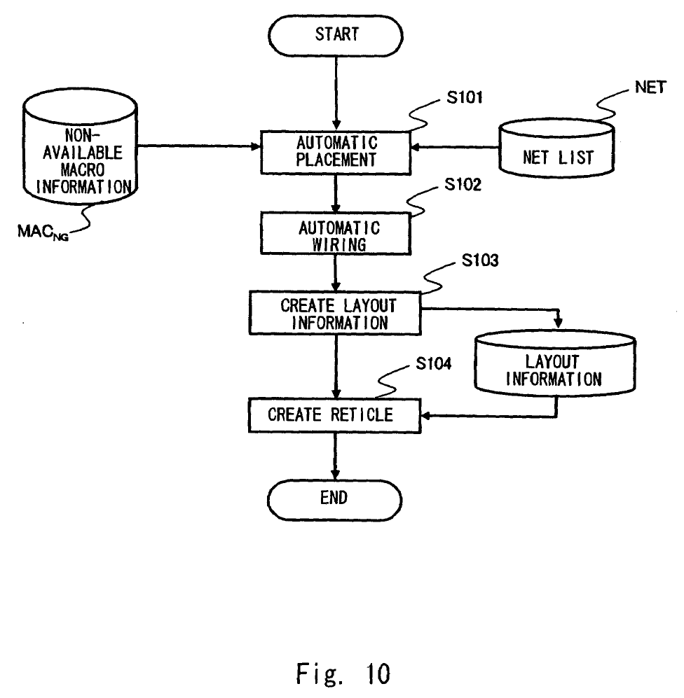

FIG. 10 is a flowchart showing processes relating to the design of a user circuit (semiconductor integrated circuit) To design the user circuit, the places of the macros to be used are specified based on the “user net list”, i.e., data expressing the circuit connection state. In an exemplary embodiment of the present invention, the non-available macro information MAC_{NG}, which is created based on the flow shown in FIG. 7, is used in this process.

At a step S101, the user circuit is formed by using only the function macros that are located in the places of the available function macros based on the user net list NET and the non-allocatable macro information MAC_{NG}. After that, wiring for connecting between function macros and between function cells is determined at a step S102.

At a step S103, wiring layout information is created based on the determined placements and wiring. At a step S104, a reticle is created from the created layout information. After that, wiring is formed on the base wafer 1 based on the reticle to produce a semiconductor integrated circuit that realizes the user circuit.

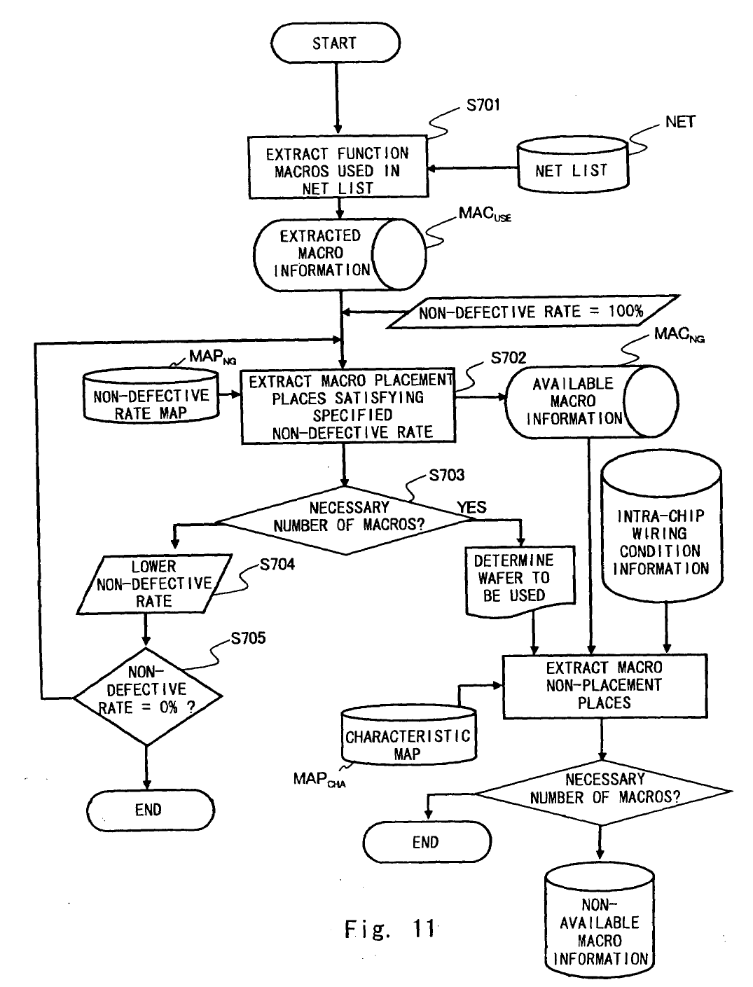

Incidentally, although the flow in which the macros that are prohibited from being placed are determined based on only the non-defective rates has been explained with FIGS. 7-10, the macro test information MT may include the characteristic map MAP_{CHA} as shown in FIG. 6. Accordingly, FIG. 11 shows a flow in which a non-allocatable map is created with consideration given to such characteristics. In FIG. 11, the same signs are assigned to the same processes as those in FIG. 7, and their explanations are omitted as appropriate.

The flow shown in FIG. 11 is different from that in FIG. 7 in that after the base wafer to be used is determined at the step S702, at the step S706 in which the places of macros that are prohibited from being placed are determined, the macros that are determined not to satisfy the circuit characteristics required for the user circuit based on the required circuit characteristics and the characteristic map are also defined as the macros that are prohibited from being used. After that, it is determined whether or not there is sufficient number of macros that are defined to be available for the placements for the user circuit with consideration also given to the characteristics. At this point, if there is not sufficient number of macros for the user circuit, the process is terminated. If there is sufficient number of macros for the user circuit, non-allocatable macro information, for which the characteristics are also taken into consideration, is created. After that, a semiconductor integrated circuit that realizes the user circuit is formed in the same flow as that in FIG. 10.

As has been explained above in detail, tests are carried out for each chip, and the test results are stored as the macro test information MT such as a non-defective rate map and a characteristic map at the phase when the base wafer is formed in an exemplary embodiment of the present invention. Then, a chip capable to carry out all of the required functions for a user circuit is selected based on information about function macros necessary for the user circuit and the macro test information, and is formed as the user circuit without using function macros that do not operate properly and function macros that do not satisfy required characteristics.

By forming a semiconductor integrated circuit in this manner, a user circuit can be constructed, even from a chip having some defects in some of its function macros, by using the remaining non-defective portions of the chip. Furthermore, yield rates in the manufacture of semiconductor integrated circuits will be improved, because even chips that have some defects in some of their function macros can be used to form user circuits, though depending on the user circuits. Furthermore, since the improvement in yield rates can reduce the number of processes necessary to produce user circuits, it is possible with certainty to reduce the number of development processes, which is one of the purposes of structured ASICs.

Exemplary embodiments in accordance with the present invention have been explained in detail, the present invention is not limited to those exemplary embodiments and various modifications may be possible to them. For example, a flow in which after the places of macros are determined based on a non-defective rate, the places of macros are further determined based on characteristics, and then these processes are repeated until the necessary number of macros are secured maybe also applicable. Furthermore, in the case in which there are several types of base wafer, it is possible to specify the type of base wafer that are actually used in the step S702, and then to carry out a similar step to the step S703 in which it is determined whether or not the necessary number of function macros are secured in all of the wafers of that type. As described above, various modifications may be possible to the exemplary embodiments by those skilled in the art without departing from the spirit of the invention.

It is apparent that the present invention is not limited to the above exemplary embodiments, but may be modified and changed without departing from the scope and spirit of the invention.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor chip, comprising:
a semiconductor substrate;
a multi-layer wiring structure on the semiconductor substrate, including a seal ring structure; and a semiconductor element arranged in an inner region of said semiconductor chip and in a frame region of said semiconductor chip,
wherein the semiconductor element comprises a chip internal circuit element, the inner region is enclosed by the seal ring structure, and the seal ring structure separates the frame region as being outside of the inner region.

2. The semiconductor chip according to claim 1, wherein the semiconductor element arranged in the frame region comprises at least one of a metal-oxide semiconductor transistor, a metal-oxide semiconductor capacitor, a diffusion layer resistor, a gate electrode resistor, a silicide resistor, and a diode.

3. The semiconductor chip according to claim 1, wherein the semiconductor element arranged in the frame region is covered by at least one of an element protecting film of an upper layer of the semiconductor substrate and the semiconductor substrate, a main layer of interlayer insulating films comprising the multi-layer wiring structure formed on an upper layer of the element protecting film comprises a different material from the element protecting film, and the main layer of the interlayer insulating films comprises a low-dielectric-constant film.

4. The semiconductor chip according to claim 2, wherein the semiconductor element arranged in the frame region is covered by at least one of an element protecting film of an upper layer of the semiconductor substrate and the semiconductor substrate, a main layer of interlayer insulating films comprises the multi-layer wiring structure formed on an upper layer of the element protecting film is comprised of a different material from the element protecting film, and the main layer of the interlayer insulating films comprises a low-dielectric-constant film.

5. The semiconductor chip according to claim 3, wherein the element protecting film comprises one of a single film and a stacked film made from at least one of SiO, SiC, SiN, SiCN, SiON, and SiN.

6. The semiconductor chip according to claim 3, wherein the seal ring structure includes a frame body area and a thinning area, the interlayer insulating film formed by the low-dielectric-constant film is formed in the frame body area, the element protecting film is formed in the thinning area, a conductive layer is formed around the inner region as a frame body and is formed superimposed in a film thickness direction in the frame body area, and the conductive film is formed intermittently in the thinning area.

7. The semiconductor chip according to claim 5, wherein the seal ring structure includes a frame body area and a thinning area, the interlayer insulating film formed by the low-dielectric-constant film is formed in the frame body area, the element protecting film is formed in the thinning area, a conductive layer is formed around the inner region as a frame body and is formed superimposed in a film thickness direction in the frame body area, and the conductive film is formed intermittently in the thinning area.

8. The semiconductor chip according to claim 6, wherein at least a part of a conductive film in the frame body area and the semiconductor substrate are electrically connected.

9. The semiconductor chip according to claim 3, wherein a wiring for connecting the semiconductor element formed in the frame region and the inner region comprises a wiring formed lower than the low-dielectric-constant film.

10. The semiconductor chip according to claim 5, wherein a wiring for connecting the semiconductor element formed in the frame region and the inner region comprises a wiring formed lower than the low-dielectric-constant film.

11. The semiconductor chip according to claim 6, wherein a wiring for connecting the semiconductor element formed in the frame region and the inner region comprises a wiring formed lower than the low-dielectric-constant film.

12. The semiconductor chip according to claim 8, wherein a wiring for connecting the semiconductor element formed in the frame region and the inner region comprises a wiring formed lower than the low-dielectric-constant film.

13. The semiconductor chip according to claim 9, wherein the wiring comprises at least one of a diffusion layer, a polycrystalline semiconductor layer, an Aluminum-based wiring, a copper-based wiring, and a silicide wiring.

14. The semiconductor chip according to claim 1, wherein the seal ring structure comprises one seal ring structure of a plurality of the seal ring structures, each seal ring structure being formed along an outer periphery of the semiconductor substrate.

15. The semiconductor chip according to claim 2 wherein the seal ring structure comprises one seal ring structure of a plurality of the seal ring structures, each seal ring structure being formed along an outer periphery of the semiconductor substrate.

16. The semiconductor chip according to claim 1, wherein the semiconductor element comprises one of a plurality of semiconductor elements, wherein a semiconductor element of the plurality of semiconductor elements is respectively arranged at each side of at least two sides configuring the frame region.

17. The semiconductor chip according to claim 2, wherein the semiconductor element comprises one of a plurality of semiconductor elements, wherein a semiconductor element of the plurality of semiconductor elements is respectively arranged at each side of at least two sides configuring the frame region.

18. A semiconductor device, comprising:
a semiconductor substrate; and
a semiconductor chip having a multi-layer wiring structure and a seal ring structure on the semiconductor substrate, wherein the semiconductor chip comprises a semiconductor element arranged in an inner region of the semiconductor chip and a frame region of the semiconductor chip, the semiconductor element comprising a chip internal circuit component, the inner region being enclosed to be inside of the seal ring structure, and the frame region is separated as outside of the inner region by the seal ring structure.

19. The semiconductor device according to claim 18, wherein the semiconductor element arranged in the frame region comprises at least one of a metal-oxide semiconductor transistor, a metal-oxide semiconductor capacitor, a diffusion layer resistor, a gate electrode resistor, a silicide resistor, and a diode.

20. The semiconductor device according to claim 18, wherein the semiconductor element arranged in the frame region is covered by at least one of an element protecting film of an upper layer of the semiconductor substrate and the semiconductor substrate, a main layer of interlayer insulating films comprising the multi-layer wiring structure formed on an upper layer of the element protecting film is comprised of a different material from the element protecting film, and the main layer of the interlayer insulating films comprises a low-dielectric-constant film.

21. A method of fabricating a semiconductor chip, said 4, 24 method comprising:
forming a semiconductor element on a substrate; and
forming a multi-layer wiring structure on the substrate, including a seal ring structure,
wherein:
the seal ring structure separates the chip into an inner region enclosed by the seal ring structure and a frame region being outside the seal ring structure, and
the semiconductor element comprises a chip internal circuit component and is located partially in the inner region and partially in the frame region.
